(19) United States
(12) Patent Application Publication
(10) Pub. No.: US 2026/0198135 A1
(43) Pub. Date: Jul. 9, 2026

(54) METHOD OF MANUFACTURING A SEMICONDUCTOR DEVICE AND SEMICONDUCTOR DEVICE

(71) Applicant: ams-OSRAM International GmbH, Regensburg (DE)

(72) Inventor: Andreas PLOESSL, Regensburg (DE)

(21) Appl. No.: 19/128,602

(22) PCT Filed: Nov. 8, 2023
(86) PCT No.: PCT/EP2023/081196

§ 371 Date: May 9, 2025

(30) Foreign Application Priority Data
Nov. 10, 2022 (DE) 10 2022 129 714.4

(51) Int. Cl. H10H 20/01

(52) U.S. Cl. CPC H10H 20/021; H10H 20/019

(57) ABSTRACT

A method of manufacturing a semiconductor device comprises epitaxially forming one or more semiconductor layers over a growth substrate, wherein a semiconductor body having a first main surface is produced. The method further comprises forming a metallic layer over the first main surface and applying a semiconductor substrate in contact with the metallic layer, wherein a material of the semiconductor substrate is selected such that a metal of the metallic layer is suitable for forming a metal-semiconductor contact with the material of the semiconductor substrate, whereby at the interface between the semiconductor substrate and the metallic layer the material of the semiconductor substrate interacts with the metal and forms a metal-semiconductor contact. The method further comprises removing the growth substrate, whereby a workpiece is obtained, and singulating the workpiece into individual semiconductor chips.

### CROSS-REFERENCE TO RELATED APPLICATIONS

This is a US national phase of international application PCT/EP2023/081196, filed on Nov. 8, 2023, which claims priority to German application DE 10 2022 129 714.4, filed on Nov. 10, 2022, the entire contents of each of which are incorporated herein by reference.

### BACKGROUND

In the manufacture of semiconductor devices, the individual components are first processed at the wafer level, for example by depositing and patterning layers, for example semiconductor layers, insulating layers and/or metallic layers. In the manufacture of optoelectronic semiconductor devices using thin-film technology, for example, generally a semiconductor body is grown on a growth substrate and is connected to a carrier, for example a semiconductor carrier, in a later method stage. Subsequently, the growth substrate is removed from the grown semiconductor body.

After processing of the individual components at the wafer level, the wafer is divided into individual semiconductor chips, for example by mechanical separation or else a combination of a laser cut and a plasma separation step.

Efforts are made to provide improved methods for producing semiconductor components.

### BRIEF DESCRIPTION OF THE DRAWINGS

The accompanying drawings serve to understand embodiments of the invention. The drawings illustrate embodiments and together with the description serve to explain them. Further embodiments and numerous of the intended advantages emerge directly from the following detailed description. The elements and structures shown in the drawings are not necessarily illustrated true to scale with respect to one another. Identical reference signs refer to identical or mutually corresponding elements and structures.

FIGS. 1A to 1G show a workpiece when carrying out a method of manufacturing a semiconductor device according to embodiments.

FIGS. 2A to 2D show a workpiece when carrying out a method of manufacturing a semiconductor device according to further embodiments.

FIG. 3 shows a workpiece when carrying out a method according to further embodiments.

FIG. 4 summarizes a method according to embodiments.

### DETAILED DESCRIPTION

In the following detailed description, reference is made to the accompanying drawings, which form part of the disclosure and in which specific embodiments are shown for illustrative purposes. In this context, directional terminology such as “top side”, “bottom side”, “front side”, “rear side”, “over”, “on”, “in front”, “behind”, “leading”, “trailing”, etc. is referred to the orientation of the figures just described. Since the components of the embodiments can be positioned in different orientations, the directional terminology serves only for explanation and is in no way restrictive.

The description of the embodiments is not restrictive since other embodiments also exist and structural or logical changes can be made without deviating from the range defined by the patent claims. In particular, elements of embodiments described below can be combined with elements of others of the described embodiments unless the context indicates otherwise.

The terms “lateral” and “horizontal” as used in this description are intended to describe an orientation or orientation which runs substantially parallel to a first surface of a substrate or semiconductor body. This may, for example, be the surface of a wafer or of a chip (die).

The horizontal direction may, for example, lie in a plane perpendicular to a growth direction during the growth of layers.

The term “vertical” as used in this description is intended to describe an orientation which runs substantially perpendicular to the first surface of a substrate or semiconductor body. The vertical direction may, for example, correspond to a growth direction during the growth of layers.

The terms “wafer” or “semiconductor substrate” which are used in the following description may comprise any semiconductor-based structure which has a semiconductor surface. Wafer and structure are to be understood to include doped and undoped semiconductors, epitaxial semiconductor layers, if appropriate supported by a base support, and further semiconductor structures. For example, a layer composed of a first semiconductor material may be grown on a growth substrate composed of a second semiconductor material, for example a GaAs substrate, a GaN substrate or a Si substrate, or of an insulating material, for example on a sapphire substrate.

It is an object of the present invention to provide an improved method of manufacturing a semiconductor device and an improved semiconductor device.

According to embodiments, the object is achieved by the subject matter of the independent claims. Advantageous developments are defined in the dependent claims.

According to embodiments, a method of manufacturing a semiconductor device comprises epitaxially forming one or more semiconductor layers over a growth substrate, wherein a semiconductor body having a first main surface is produced. The method further comprises forming a metallic layer over the first main surface and applying a semiconductor substrate in contact with the metallic layer. A material of the semiconductor substrate is selected such that a metal of the metallic layer is suitable for forming a metal-semiconductor contact with the material of the semiconductor substrate, whereby at the interface between the semiconductor substrate and the metallic layer the material of the semiconductor substrate interacts with the metal and forms a metal-semiconductor contact. The method further comprises removing the growth substrate, whereby a workpiece is obtained, and singulating the workpiece into individual semiconductor chips. The method may further comprise patterning the metallic layer before applying the semiconductor substrate.

For example, the method may further comprise applying a functional region over the semiconductor body before applying the metallic layer.

A surface of the functional region may, for example, be patterned before applying the metallic layer.

According to embodiments, the singulating may be performed by a plasma separation method.

The material of the semiconductor substrate interacts with the metal at the interface between the semiconductor substrate and the metallic layer and forms a metal-semiconductor contact. For example, the metal of the metallic layer may be suitable for reacting with the material of the semiconductor substrate. For example, a metal compound is formed at the interface between the semiconductor substrate and the metallic layer.

According to embodiments, the semiconductor substrate may be a silicon substrate and a metal silicide is formed at the interface.

According to further examples, the material of the semiconductor substrate may also partially dissolve in the metal. Furthermore, the metal may partially dissolve in the semiconductor substrate. Accordingly, for example, metal with some dissolved semiconductor material may be present on the metal side of the metal-semiconductor contact. Furthermore, semiconductor material with some dissolved metal may be present on the semiconductor side of the metal-semiconductor contact.

For example, the semiconductor substrate may be applied at a contact pressure greater than 0.5 bar (50 kPa). Furthermore, the semiconductor substrate may, for example, be applied at a temperature of at least 20° C. The temperature may also be greater, for example 180° C. or more. For example, a first contact may be performed at room temperature, and the temperature may subsequently be increased, for example to 200° C. or more.

According to embodiments, the semiconductor body may comprise a first semiconductor layer of a first conductivity type and a second semiconductor layer of a second conductivity type. The semiconductor substrate may be electrically connected to the first or the second semiconductor layer.

According to embodiments, a semiconductor device comprises a semiconductor body comprising one or more semiconductor layers and a metallic layer arranged over the semiconductor body, wherein the metallic layer comprises at a surface a material selected from platinum, palladium, nickel, aluminum, titanium, tantalum, tungsten, molybdenum, gallium or indium. The semiconductor device further comprises a silicon substrate over the metallic layer, wherein at an interface between the silicon substrate and the metallic layer a metal silicide selected from platinum silicide, palladium silicide, nickel silicide, titanium silicide, tantalum silicide, tungsten silicide or molybdenum silicide or an aluminum-silicon contact, gallium-silicon contact or indium-silicon contact is present.

According to embodiments, the semiconductor body may comprise a first semiconductor layer of a first conductivity type and a second semiconductor layer of a second conductivity type. The silicon substrate may be electrically connected to the first or the second semiconductor layer.

The semiconductor device may further comprise a functional region between the semiconductor body and the silicon substrate.

Depending on the intended use, the semiconductor may be based on a direct or an indirect semiconductor material. Examples of semiconductor materials particularly suitable for generating electromagnetic radiation comprise, in particular, nitride semiconductor compounds by which, for example, ultraviolet, blue or longer-wave light can be generated, such as, for example, GaN, InGaN, AlN, AlGaN, AlGaInN, AlGaInBN, phosphide semiconductor compounds by which, for example, green or longer-wave light can be generated, such as, for example, GaAsP, AlGaInP, GaP, AlGaP, and further semiconductor materials such as GaAs, AlGaAs, InGaAs, AlInGaAs, SiC, ZnSe, ZnO, Ga₂ O₃, diamond, hexagonal BN and combinations of the materials mentioned. The stoichiometric ratio of the compound semiconductor materials may vary. Further examples of semiconductor materials may comprise silicon, silicon-germanium and germanium.

The term “substrate” generally comprises insulating, conductive or semiconductor substrates.

In the processing of semiconductor devices, layers, for example semiconductor layers, insulating layers, conductive or metallic layers, can be patterned using photolithographic methods which are generally known. Furthermore, etching methods, for example wet-chemical or dry etching methods, or lift-off methods, inter alia, can be used for the patterning.

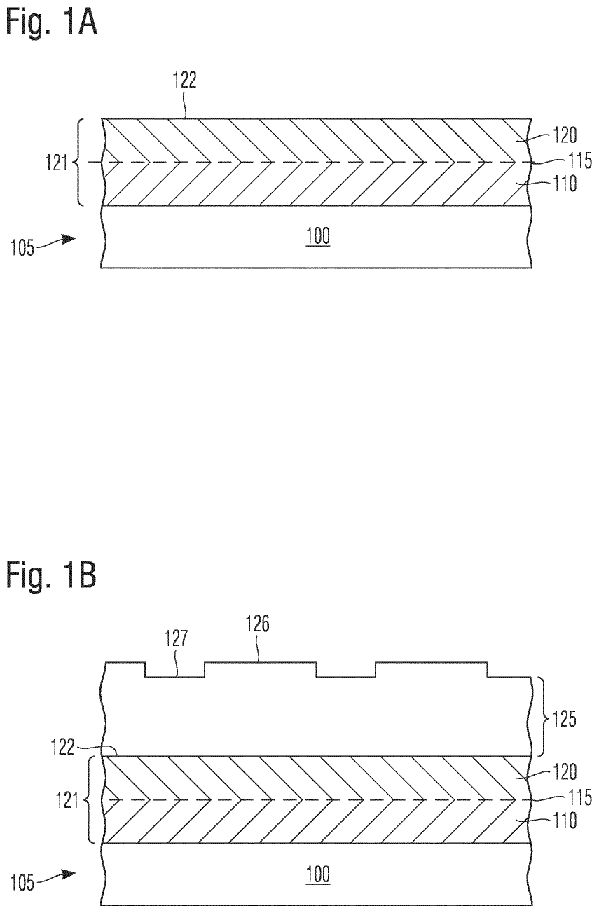

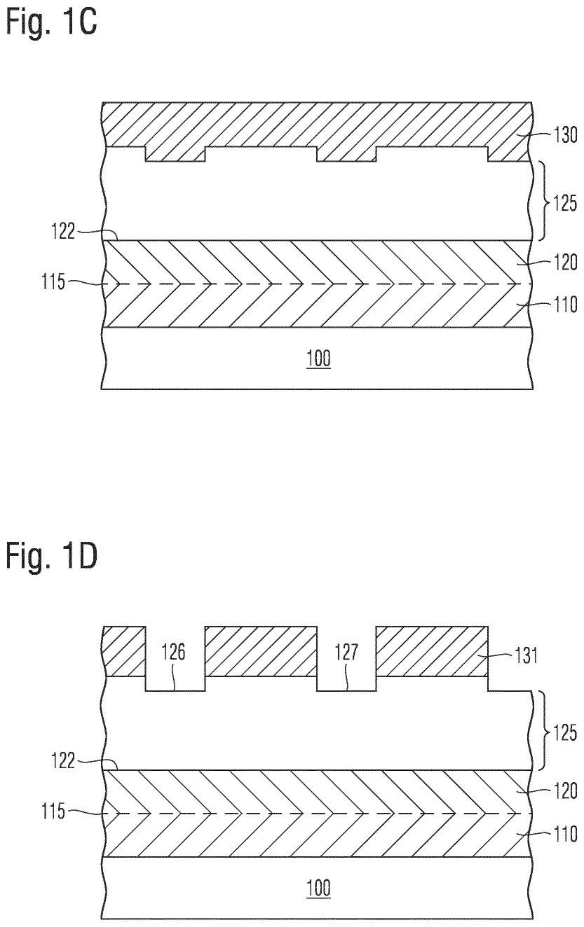

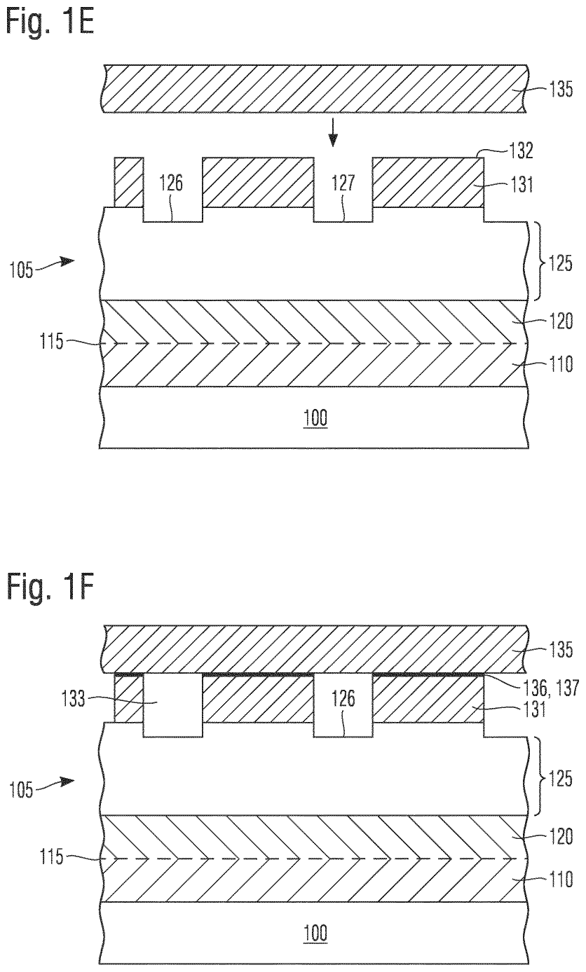

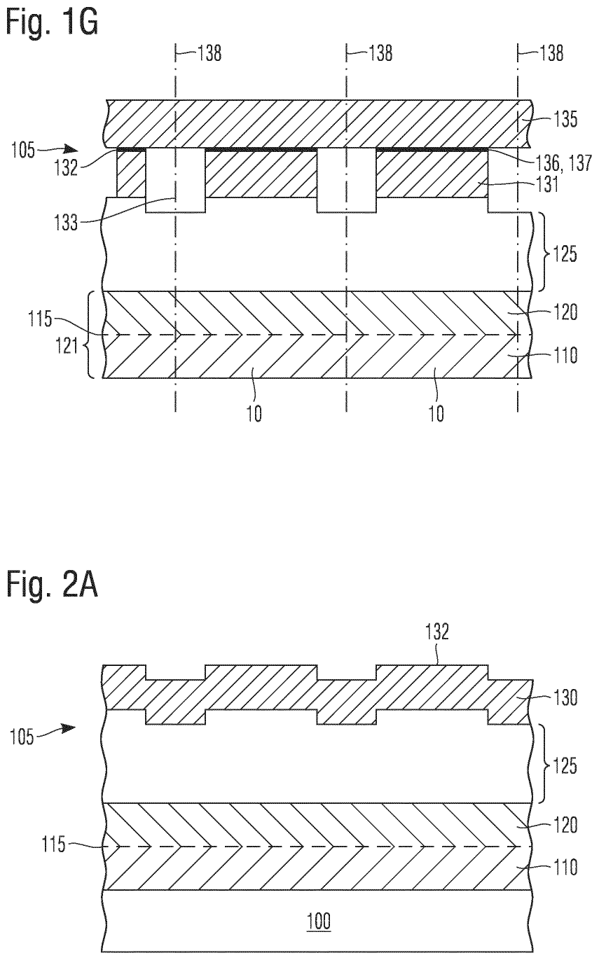

FIG. 1A shows a workpiece 105 when carrying out a method of manufacturing a semiconductor device. For example, as shown in FIG. 1A, one or more semiconductor layers are formed over a suitable growth substrate 100. Suitable examples of materials of the growth substrate and of the semiconductor layers will be specified below. For example, a first semiconductor layer 110 of a first conductivity type, for example n-conductive, is epitaxially formed over the growth substrate 100. Subsequently, a second semiconductor layer 120 of a second conductivity type, for example p-conductive, is formed over the first semiconductor layer 110. As a result, a semiconductor layer stack or semiconductor body 121 having a first main surface 122 is obtained.

The term “semiconductor body” as used in the context of the present disclosure may comprise one or more semiconductor layer(s) which may be stacked one above the other. For example, the term “semiconductor body” may also comprise only a single semiconductor layer. The different semiconductor layers may, for example, have a different composition ratio and/or a different dopant concentration and/or a different doping type.

An active zone 115 may be arranged between the first and the second semiconductor layer 110, 120. The active zone 115 may, for example, comprise a pn junction, a double heterostructure, a single quantum well (SQW) structure or a multi quantum well (MQW) structure for generating radiation. The term “quantum well structure” here does not have any significance with regard to the dimensionality of the quantization. It thus comprises, inter alia, quantum wells, quantum wires and quantum dots and also any combination of these layers.

Subsequently, a functional region 125 may be formed over the first main surface 122 of the semiconductor body 121. The term “functional region” here denotes any desired layers, for example conductive, metallic, insulating and/or semiconductor layers, which are suitable for providing a suitable functionality of the semiconductor component. Examples comprise, inter alia, mirror layers, conductive layers for producing contacts, conductive layers for rewiring and further layers. The individual layers which form the functional region 125 may be suitably patterned. According to embodiments, the functional region 125 may be patterned for forming later singulation regions. For example, recesses 127 may be formed in the surface 126 of the functional region 125. According to further embodiments, the surface 126 of the functional region 125 may also be planar.

FIG. 1B shows a view of a resulting workpiece.

Then, as illustrated in FIG. 1C, a metallic layer 130 is formed over the first main surface 122 of the semiconductor body 121. For example, the metallic layer 130 may comprise one or more metallic layers. Examples of suitable materials of the metallic layer 130 will be specified below.

As shown in FIG. 1D, the metallic layer 130 may be patterned, resulting in a patterned metallic layer 131. The patterned metallic layer 131 is arranged over the first main surface 122 of the semiconductor body. As further shown in FIG. 1D, the metallic layer may be patterned such that ridges of the metallic layer 130 are arranged between the recesses 127. More specifically, the recesses 127 of the functional region 125 are arranged between adjacent ridges of the patterned metallic layer 131.

Subsequently, as shown in FIG. 1E, a suitable semiconductor substrate 135 is connected to the workpiece 105. For example, a contact pressure greater than 0.5 bar (50 kPa) may be present when connecting the semiconductor substrate 135 to the workpiece. Furthermore, a temperature in this method step may be 20° C. or more. The temperature may also be higher and, for example, be increased to 180° C. or more after a first contact. A semiconductor material of the semiconductor substrate 135 is selected such that a metal of the metallic layer 130 is suitable for reacting or interacting with the semiconductor material of the semiconductor substrate, such that a metal-semiconductor contact 137 is formed. If the metallic layer 130 comprises a plurality of partial layers arranged one above the other, the metal of the partial layer which is brought into contact with the semiconductor substrate 135 is selected such that it reacts or interacts with the material of the semiconductor substrate 135.

For example, a metal-semiconductor compound 136 may form.

The metallic layer 130 remains on a side facing away from the interface.

According to embodiments, a material of the semiconductor substrate 135 may be silicon and a metal of the metallic layer 130 may be suitable for forming a metal silicide. According to further embodiments, the metal of the metallic layer may also partially dissolve in silicon.

Furthermore, silicon may also partially dissolve in the metal. Accordingly, a solid-state reaction takes place during joining, by means of which a metal/semiconductor contact is produced. At the same time, a mechanical and thermal coupling of the metallic layer 130 to the silicon substrate 135 is also brought about. This transfer step may be carried out such that soldering, eutectic bonding, isothermal solidification, adhesive bonding or metal/metal bonding, for example in the variant of so-called direct wafer bonding or thermocompression, may be dispensed with.

FIG. 1F shows a cross-sectional view of a resulting workpiece 105. As can be seen, the semiconductor substrate 135 is now arranged over the metallic patterned layer 131. Cavities 133 may be present between the surface 126 of the functional region 125 and the semiconductor substrate 135. At the interface between the semiconductor substrate 135 and the metallic layer 130, the material of the semiconductor substrate may react or interact with the metal, such that a metal compound 136 or a metal-semiconductor contact 137 is formed. A metal compound 136 is thus present, for example, at the interface between metallic layer 130 and semiconductor substrate 135. The cavities 133 form, for example, a singulation region at which the individual chips are to be divided later. This singulation region 138 is free of metal, such that negative reactions are not to be expected in a subsequent singulation step.

As shown in FIG. 1G, the growth substrate 100 is subsequently removed from the workpiece 105. Then, the individual chips may be singulated along the singulation regions 138. This singulation may comprise, for example, a plasma etching process. Due to the fact that no metal is present in the singulation regions 138, a plasma etching process may be carried out without problems due to metal residues in the region of the singulation region 138 being to be expected.

FIG. 1G furthermore shows a cross-sectional view of a semiconductor component 10 according to embodiments. The semiconductor component 10 shown in FIG. 1G comprises a semiconductor body 121. The semiconductor body 121 may comprise one or more semiconductor layers 110, 120. For example, the semiconductor body comprises a first semiconductor layer 110 of a first conductivity type, for example n-conductive, and a second semiconductor layer of a second conductivity type, for example p-conductive. An active zone 115 for generating or receiving radiation may be arranged between the first and the second semiconductor layer 110, 120. A metallic layer 131 is arranged over the semiconductor body. The metallic layer 131 comprises at its surface 132 a material selected from platinum, palladium, nickel, aluminum, titanium, tantalum, tungsten, molybdenum, gallium or indium. Furthermore, the semiconductor device 10 comprises a silicon substrate 135 at the metallic layer 130. A metal silicide is present at an interface between the silicon substrate 135 and the metallic layer 130. The metal silicide is selected from platinum silicide, palladium silicide, nickel silicide, titanium silicide, tantalum silicide, tungsten silicide or molybdenum silicide. Alternatively, when using aluminum or gallium or indium as material of the metallic layer 131, an aluminum-silicon contact or gallium or indium-silicon contact may be present at the interface between the silicon substrate 135 and the metallic layer 130. For example, a zone may be present in silicon with aluminum or gallium or indium dissolved in silicon and a zone may be present in aluminum or gallium or indium with silicon dissolved in aluminum or gallium or indium.

For example, the semiconductor device 10 may be an optoelectronic semiconductor device which is suitable for emitting or receiving electromagnetic radiation. The silicon substrate 135 serves firstly for mechanical stabilization. Secondly, the silicon substrate 135 may be heavily doped. The silicon substrate 135 may produce an electrical connection to the metallic layer 130. Furthermore, the silicon substrate 135 may dissipate heat from the semiconductor device 10. The semiconductor device 10 may be, for example, a mechanically particularly robust component since the semiconductor substrate is monocrystalline and is present without mechanical damage from laser or mechanical separation methods.

A functional region 125 may be arranged between the semiconductor body 121 and the metallic layer 131. For example, the functional region 125 may comprise lines, for example for rewiring or for contacting. Furthermore, the functional region 125 may contain mirror layers. For example, the metallic layer 131 may be electrically connected to the second semiconductor layer 120 or the first semiconductor layer 110.

According to further embodiments, proceeding from the structure illustrated in FIG. 1B, the metallic layer 130 may also be formed as a conformal layer, such that the surface of the metallic layer 130 comprises recesses.

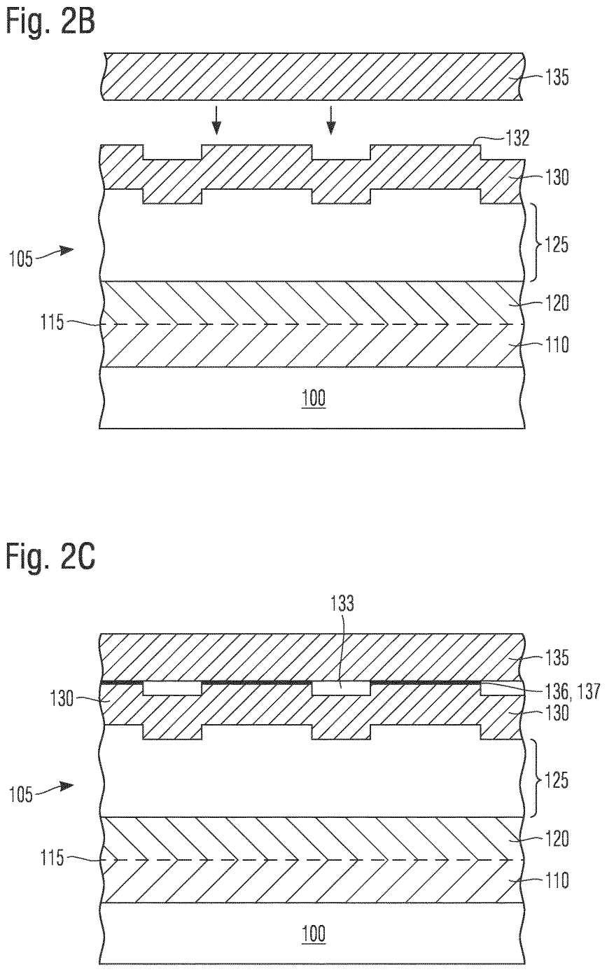

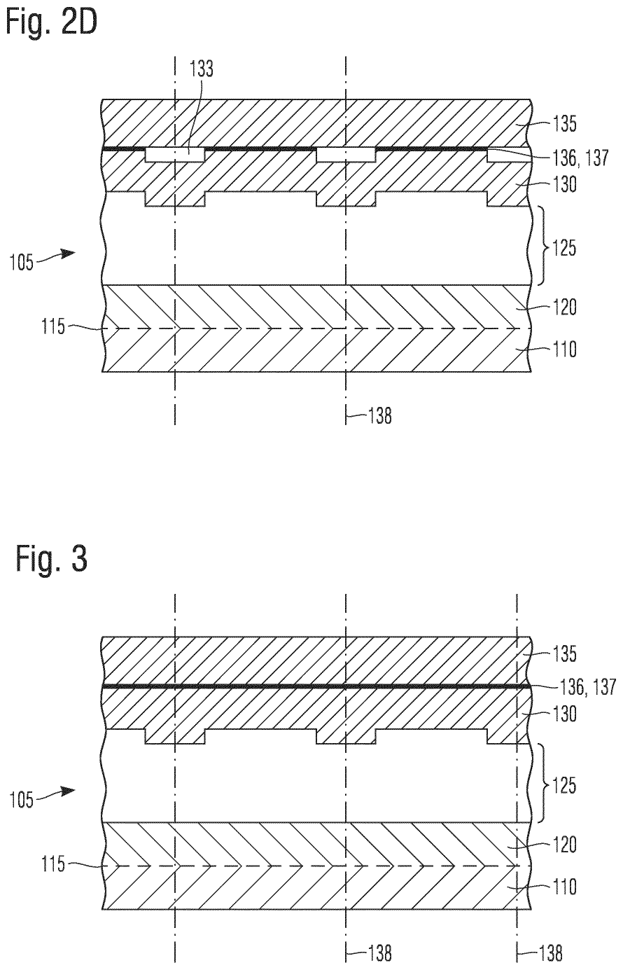

FIG. 2A shows a cross-sectional view of a resulting workpiece 105. As can be seen, the metallic layer 130 is formed such that recesses are formed in the first main surface 132 of the metallic layer.

Subsequently, as illustrated in FIG. 2B, a semiconductor substrate 135 is applied in contact with the metallic layer 130. Similarly as described with reference to FIGS. 1A to 1G, a metal compound 136 or metal-semiconductor contact 137 is formed at the interface between the semiconductor substrate 135 and the metallic layer 130.

FIG. 2C shows an example of a resulting workpiece. As can be seen, cavities 133 are formed between the metallic layer 130 and the semiconductor substrate 135.

As illustrated in FIG. 2D, the growth substrate 100 may subsequently be removed. Furthermore, the workpiece 105 may be divided into individual chips. For example, the division may be performed along singulation regions 138. The singulation regions 138 correspond, for example, to the position of the cavities 133.

As has been described, a singulation of the workpiece 105 into individual chips is simplified since the semiconductor substrate 135 is connected to the metallic layer 130 without, for example, solder material or adhesive. Accordingly, a singulation method may be simplified.

For example, the singulation method may also be simplified if the semiconductor substrate 135 is connected to a metallic layer 130 having a planar first main surface. FIG. 3 shows an example of a resulting workpiece. As can be seen, in this case the semiconductor substrate 135 is connected over the entire area to the metallic layer 130. A metal-semiconductor compound 136 or a metal-semiconductor contact 137 is formed at the interface between the semiconductor substrate 135 and the metallic layer 130. For example, in this case the metallic layer may contain materials which are easily etchable, such that singulation into individual chips may be effected in a simple manner.

As has been described, a method for singulating, for example, a wafer into individual chips may be simplified by the described method for connecting the workpiece 105 to a metallic layer 130 and the semiconductor substrate 135. For example, a preceding laser cutting process is no longer required. Mechanical damage, for example, by the laser separation process for removing metallic layers in the singulation region 138 is thereby avoided or reduced. As a result, the fracture stability of the chips is increased.

Furthermore, different metal residues at the laser cutting flank may be dispensed with. In this way, a more precise control of the plasma etching process may be achieved, since influencing of the etching chemistry by metal residues is reduced. Furthermore, the reliability of the semiconductor devices in moisture may be increased, since uncontrolled galvanic elements at the component flank are dispensed with.

As has been described, according to embodiments, the singulation regions 138 may be defined exclusively photolithographically. For example, in this case, safety margins for adjustment deviations may be dispensed with. As a result, the component density on a wafer may be increased by narrower singulation regions 138. The semiconductor device 10 described may thus be placed at very small distances.

Since a solder material and the at least transient liquid phase during the soldering process may be dispensed with, barriers may become unnecessary or be calculated more weakly. As a result, the metallic layers, for example the construction and composition of the metallic layers, may be further simplified.

### Example 1

According to Example 1, the growth substrate 100 may be a GaAs substrate, and the first and the second semiconductor layer may each be AlₓGa_{y}In_{1-x-y}As layers. The metallic layer 130 may comprise a metal layer stack which is applied in a photolithographically defined manner, for example by lift-off or etching techniques. An uppermost layer of the metal layer stack or the metallic layer 130 may contain platinum or consist of platinum. The semiconductor substrate 135 may be a silicon substrate having a (100) orientation. For example, the silicon substrate is freed from a natural silicon dioxide layer and terminated with hydrogen in a dilute aqueous hydrofluoric acid solution before joining. In the connecting step, the platinum layer is pressed onto the silicon surface under uniaxial pressure, for example at 500 kPa and a temperature of, for example, 600 K. As a result, roughness peaks are flattened and the formation of platinum silicide is initiated. The semiconductor device described may be, for example, an LED (light-emitting diode) which emits electromagnetic radiation in the infrared range. According to further embodiments, the semiconductor device described may be a laser, for example an edge-emitting laser or a surface-emitting laser, for example a VCSEL (vertical cavity surface emitting laser) or a VECSEL (vertical external cavity surface emitting laser).

### Example 2

For a light-emitting diode or laser emitting in the red wavelength range, the growth substrate 100 may be a GaAs substrate. The first and the second semiconductor layers may each be AlxGayIn1-x-yP layers. The metallic layer 130 may contain palladium as the uppermost metal. For example, a silicon substrate 135 having a (111) orientation may be used. With this crystal orientation, a more stable hydrogen termination and a more even surface is achieved.

Before joining, the silicon substrate 135 is treated with an aqueous hydrofluoric acid solution buffered with ammonium fluoride. Subsequently, the silicon substrate 135 is joined to the workpiece 105 under similar conditions as in Example 1. Palladium absorbs the hydrogen particularly easily and thus already initiates silicide formation under particularly mild conditions.

### Example 3

For an LED or a laser emitting in the far UV range, a layer stack containing AlₓGa_{y}In_{1-x-y}N layers is grown over a GaAs growth substrate. The metallic layer 130 may, for example, contain nickel or consist of nickel. For example, a very thin gold layer protecting against oxidation in ambient air may additionally be applied. During joining with a silicon substrate 135, the Au layer diffuses into the silicon and into the nickel layer, exposes the reactive nickel and thus leads to nickel silicide formation with the H-terminated silicon substrate 135.

### Example 4

For an LED or laser emitting in a blue wavelength range, a semiconductor body is grown over a growth substrate 100, which may be, for example, a GaAs substrate. The individual semiconductor layers may, for example, each be AlₓGa_{y}In_{1-x-y}P layers. According to embodiments, during processing, recesses 126 are applied in the surface of the functional region 125. Then, a metallic layer 130 is applied over the entire area. For example, the metallic layer may contain an aluminum layer as the uppermost layer. This may be produced, for example, by cathode sputtering. The joining with the silicon substrate 135 is performed, for example, in an inert atmosphere at a very low oxygen partial pressure. Accordingly, the aluminum-containing surface is protected against oxidation. When connecting the workpiece to the silicon substrate 135 under pressure and temperature, the residual oxide on the silicon substrate 135 is reduced by aluminum. The interdiffusion of aluminum and silicon ensures a mechanically stable low-ohmic metal/semiconductor contact.

In the preceding examples, silicon is used as material of the semiconductor substrate 135. Established plasma etching processes for separation are present. Furthermore, silicon has good mechanical stability, robustness in moisture and good thermal conductivity. A (111) crystal orientation brings about improved H termination. According to embodiments, however, other crystal orientations may also be used. Furthermore, further materials may be used as semiconductor substrate 135. In particular, germanium may be used.

For example, a patterning of the surface of the functional region 125 may be performed such that no recesses 127 are present at the edge of the wafer. Accordingly, the recesses 127 form an extended void 133 which is closed with respect to the environment. In this way, it may be prevented that contaminants or process chemicals penetrate in subsequent processes.

Recesses 127 which go through, on the other hand, may facilitate breakouts from the epitaxially grown semiconductor body in a laser process for removing the growth substrate 100. According to embodiments, the semiconductor body may furthermore be etched to form a mesa. This mesa etching may be carried out before or after removing the growth substrate 100. For example, the mesa etching may be performed from the side of the first semiconductor layer 110 or from the side of the second semiconductor layer 120.

As has been described, the semiconductor substrate 135 may also be applied over a metallic layer 130 which is applied over the entire area and which is not patterned. In this case, for example, a more easily etchable metallic layer may be formed in contact with the semiconductor material.

As has been described, a metal silicide may be present at an interface between the silicon substrate 135 and the metallic layer 130. This may be selected, for example, from platinum silicide, palladium silicide, nickel silicide, titanium silicide, tantalum silicide, tungsten silicide or molybdenum silicide. According to further embodiments, an aluminum-silicon contact, gallium-silicon contact or indium-silicon contact may be present at the interface. This selection is attributable to the fact that the semiconductor substrate 135 is not connected to the workpiece 105 by soldering. Instead, the silicon substrate 135 is connected to the workpiece 105 using pressure and temperature, such that a solid-state reaction takes place between the silicon substrate 135 and the metallic layer 130. In this way, a metal semiconductor contact 137 is produced.

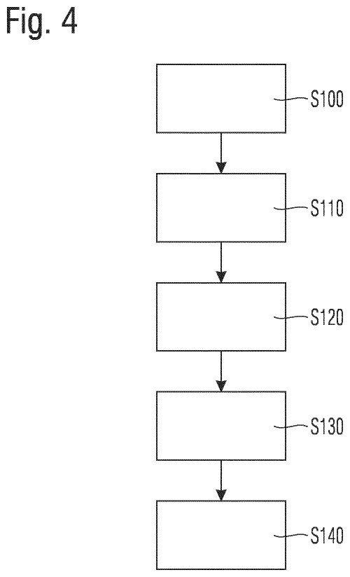

FIG. 4 summarizes a method of manufacturing a semiconductor device according to embodiments. The method comprises epitaxially forming (S100) one or more semiconductor layers over a growth substrate, wherein a semiconductor body having a first main surface is produced. The method further comprises forming (S110) a metallic layer over the first main surface and applying (S120) a semiconductor substrate in contact with the metallic layer, wherein a material of the semiconductor substrate is selected such that a metal of the metallic layer is suitable for forming a metal-semiconductor contact with the material of the semiconductor substrate, whereby at the interface between the semiconductor substrate and the metallic layer the material of the semiconductor substrate interacts with the metal and forms a metal-semiconductor contact. The method further comprises removing (S130) the growth substrate, whereby a workpiece is obtained, and singulating (S140) the workpiece into individual semiconductor chips.

Although specific embodiments have been illustrated and described herein, those skilled in the art will recognize that the specific embodiments shown and described may be replaced by a multiplicity of alternative and/or equivalent configurations without departing from the scope of the invention. The application is intended to cover any adaptations or variations of the specific embodiments discussed herein. Therefore, the invention is limited only by the claims and the equivalents thereof.

### LIST OF REFERENCES

10 semiconductor device
100 growth substrate
105 workpiece
110 first semiconductor layer
115 active zone
120 second semiconductor layer
121 semiconductor body
122 first main surface of the semiconductor body
125 functional region
126 surface of the functional region
127 recess
130 metallic layer
131 patterned metallic layer
132 first main surface of the metallic layer
133 void
135 semiconductor substrate
136 metal semiconductor compound
137 metal semiconductor contact
138 singulation region

1. A method of manufacturing a semiconductor device comprising:
epitaxially forming one or more semiconductor layers, over a growth substrate, wherein a semiconductor body having a first main surface is produced;
forming metallic layer over the first main surface;
patterning the metallic layer after forming the metallic layer over the first main surface;
applying a semiconductor substrate in contact with the metallic layer after patterning the metallic layer, wherein a semiconductor material of the semiconductor substrate is selected such that a metal of the metallic layer is suitable for forming a metal-semiconductor contact with the material of the semiconductor substrate, whereby at the interface between the semiconductor substrate and the metallic layer the material of the semiconductor substrate interacts with the metal and forms a metal-semiconductor contact and the metallic layer remains on a side facing away from the interface;
removing the growth substrate, whereby a workpiece is obtained; and
singulating the workpiece into individual semiconductor chips.

2. The method according to claim 1, wherein the metal of the metallic layer is suitable for reacting with the material of the semiconductor substrate and a metal compound is formed at the interface between the semiconductor substrate and the metallic layer.

3. (canceled)

4. The method according to claim 1, further comprising applying a functional region over the semiconductor body before applying the metallic layer.

5. The method according to claim 4, further comprising patterning a surface of the functional region before applying the metallic layer.

6. The method according to claim 1, wherein the singulating is performed by a plasma separation method.

7. The method according to claim 1, wherein the semiconductor substrate is a silicon substrate and a metal silicide is formed at the interface.

8. The method according to claim 1, wherein the semiconductor substrate is applied at a contact pressure greater than 0.5 bar (50 kPa).

9. The method according to claim 1, wherein the semiconductor substrate is applied at a temperature greater than 180° C.

10. The method according to claim 1, wherein the semiconductor body comprises a first semiconductor layer of a first conductivity type and a second semiconductor layer of a second conductivity type and the semiconductor substrate is electrically connected to the first or the second semiconductor layer.

11. A semiconductor device, comprising:
a semiconductor body comprising one or more semiconductor layers,
a metallic layer arranged over the semiconductor body, wherein the metallic layer comprises at a surface a material selected from platinum, palladium, nickel, aluminum, titanium, tantalum, tungsten, molybdenum, gallium or indium,
wherein the metallic layer is patterned so that an edge portion of the semiconductor device is free of the metallic layer;
a silicon substrate over the metallic layer, wherein at an interface between the silicon substrate and the metallic layer a metal silicide selected from platinum silicide, palladium silicide, nickel silicide, titanium silicide, tantalum silicide, tungsten silicide or molybdenum silicide or an aluminum-silicon contact, gallium-silicon contact or indium-silicon contact is present.

12. The semiconductor device according to claim 11, wherein the semiconductor body comprises a first semiconductor layer of a first conductivity type and a second semiconductor layer of a second conductivity type and the silicon substrate is electrically connected to the first or the second semiconductor layer.

13. The semiconductor device according to claim 11, further comprising a functional region between the semiconductor body and the silicon substrate.

14. The method according to claim 1, wherein singulating is effected in singulation regions which are free of the metallic layer.
